(19) United States
(12) Patent Application Publication
(10) Pub. No.: US 2024/0429206 A1
(43) Pub. Date: Dec. 26, 2024

(54) SEMICONDUCTOR DEVICE

(71) Applicant: FUJI ELECTRIC CO., LTD., Kawasaki-shi (JP)

(72) Inventor: Yuichiro HINATA, Matsumoto-city, Nagano (JP)

(73) Assignee: FUJI ELECTRIC CO., LTD., Kawasaki-shi (JP)

(21) Appl. No.: 18/643,067

(22) Filed: Apr. 23, 2024

(30) Foreign Application Priority Data
Jun. 22, 2023 (JP) 2023-102705

(51) Int. Cl. H01L 25/07; H01L 23/00; H01L 23/31; H01L 23/498

(52) U.S. Cl. CPC H01L 25/072; H01L 23/3107; H01L 23/49822; H01L 23/49844; H01L 24/08; H01L 2224/08238; H01L 2224/08245; H01L 2924/13091

(57) ABSTRACT

A semiconductor device includes: an insulated circuit substrate; a semiconductor chip provided on a top surface side of the insulated circuit substrate; a sealing resin provided so as to seal the semiconductor chip; a first external terminal electrically connected to the semiconductor chip so as to be exposed on a first side surface of the sealing resin; a second external terminal electrically connected to the semiconductor chip and having a part opposed parallel to the first external terminal on an upper side of the first external terminal so as to be exposed on a top surface of the sealing resin; and a first insulating member interposed between the first external terminal and the second external terminal.

### CROSS-REFERENCE TO RELATED APPLICATION

This application claims benefit of priority under 35 USC 119 based on Japanese Patent Application No. 2023-102705 filed on Jun. 22, 2023, the entire contents of which are incorporated by reference herein.

### BACKGROUND OF THE INVENTION

### 1. Field of the Invention

The present invention relates to semiconductor devices.

### 2. Description of the Related Art

WO2022/054560A1 discloses a semiconductor device including a socket arranged on the inner side of an outer edge of a sealing member in a direction in which a semiconductor element and a metallic member overlap with each other, and discloses that the semiconductor device can be a power conversion device having three levels or multiple levels. JP2007-234693A discloses a semiconductor device including a positive-side external connection terminal and a negative-side external connection terminal separately overlapping with each other so as to be exposed on a top surface of the semiconductor device.

JP2004-153243A discloses a semiconductor device having a structure in which insulating sheets are inserted between the respective electrodes exposed on a top surface of a case. JP2022-67815A discloses a semiconductor device including a side-surface terminal and top-surface terminals.

JP2017-118816A discloses a three-level semiconductor module including three main terminals that are arranged parallel to each other inside the module.

Development in power semiconductor modules has been promoted that have a configuration in which a plurality of external terminals are deposited close to each other (laminated) so as to be opposed parallel to each other and project from a side surface of a sealing resin in order to reduce a wiring inductance. However, arranging the plural external terminals having the parts projecting from the sealing resin in a stepped manner so as to be connected to an external circuit impedes a reduction in the entire size of such a power semiconductor module.

### SUMMARY OF THE INVENTION

In view of the foregoing problems, the present invention provides a semiconductor device including a plurality of external terminals arranged to be opposed parallel to each other while achieving a reduction in size.

An aspect of the present invention inheres in a semiconductor device including: an insulated circuit substrate; a semiconductor chip provided on a top surface side of the insulated circuit substrate; a sealing resin provided so as to seal the semiconductor chip; a first external terminal electrically connected to the semiconductor chip so as to be exposed on a first side surface of the sealing resin; a second external terminal electrically connected to the semiconductor chip and having a part opposed parallel to the first external terminal on an upper side of the first external terminal so as to be exposed on a top surface of the sealing resin; and a first insulating member interposed between the first external terminal and the second external terminal.

### BRIEF DESCRIPTION OF THE DRAWINGS

FIG. 1 is a circuit diagram illustrating an example of a semiconductor device according to a first embodiment;

FIG. 2 is a plan view illustrating the example of the semiconductor device according to the first embodiment;

FIG. 3 is a side view illustrating the example of the semiconductor device according to the first embodiment;

FIG. 4 is another plan view illustrating the example of the semiconductor device according to the first embodiment

FIG. 5 is a cross-sectional view illustrating the example of the semiconductor device according to the first embodiment;

FIG. 6 is a cross-sectional view illustrating an example of a metal die and the semiconductor device according to the first embodiment;

FIG. 7 is a circuit diagram illustrating a semiconductor device of a first comparative example;

FIG. 8 is a plan view illustrating the semiconductor device of the first comparative example;

FIG. 9 is a side view illustrating the semiconductor device of the first comparative example;

FIG. 10 is another plan view illustrating the semiconductor device of the first comparative example;

FIG. 11 is a cross-sectional view illustrating the semiconductor device of the first comparative example;

FIG. 12 is a cross-sectional view illustrating a metal die and the semiconductor device of the first comparative example;

FIG. 13 is a plan view illustrating a semiconductor device of a second comparative example;

FIG. 14 is a side view illustrating the semiconductor device of the second comparative example;

FIG. 15 is a cross-sectional view illustrating the semiconductor device of the second comparative example;

FIG. 16 is a cross-sectional view illustrating an example of a semiconductor device according to a second embodiment;

FIG. 17 is a plan view illustrating an example of a semiconductor device according to a third embodiment;

FIG. 18 is a plan view illustrating a semiconductor device implementing a two-level circuit;

FIG. 19 is a cross-sectional view illustrating an example of a semiconductor device according to a fourth embodiment;

FIG. 20 is a cross-sectional view illustrating an example of a metal die and the semiconductor device according to the fourth embodiment;

FIG. 21 is a cross-sectional view illustrating an example of a semiconductor device according to a fifth embodiment;

FIG. 22 is a cross-sectional view illustrating an example of a metal die and the semiconductor device according to the fifth embodiment; and

FIG. 23 is a cross-sectional view illustrating an example of a semiconductor device according to a sixth embodiment.

### DETAILED DESCRIPTION

With reference to the drawings, first to sixth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Moreover, in some drawings, portions are illustrated with different dimensional relationships and proportions. The first to sixth embodiments described below merely illustrate schematically devices and methods for specifying and giving shapes to the technical idea of the present invention, and the span of the technical idea is not limited to materials, shapes, structures, and relative positions of elements described herein.

Additionally, definitions of directions such as “upper and lower” and “left and right” in the following description are simply definitions for convenience of description, and do not limit the technological concept of the present invention. For example, when observing an object rotated by 90 degrees, the “upper and lower” is converted to “left and right” to be read, and when observing an object rotated by 180 degrees, the “upper and lower” are read reversed, which should go without saying.

In the following description, a “first main electrode” of a semiconductor chip means an electrode through which a main current flows into or flows out of the semiconductor chip. The “first main electrode” is assigned to any one of a source electrode or a drain electrode when the semiconductor chip implements a field-effect transistor (FET) or a static induction transistor (SIT). The “first main electrode” is assigned to any one of an emitter electrode or a collector electrode when the semiconductor chip implements an insulated-gate bipolar transistor (IGBT). The “first main electrode” is assigned to any one of an anode electrode or a cathode electrode when the semiconductor chip implements a static induction (SI) thyristor or a gate turn-off (GTO) thyristor. A “second main electrode” of the semiconductor chip is assigned to any one of the source electrode or the drain electrode, which is not assigned as the first main electrode, when the semiconductor chip implements the FET or the SIT. The “second main electrode” is assigned to any one of the emitter electrode or the collector electrode, which is not assigned as the first main electrode, when the semiconductor chip implements the IGBT. The “second main electrode” is assigned to any one of the anode electrode or the cathode electrode, which is not assigned as the first main electrode, when the semiconductor chip implement the SI thyristor or the GTO thyristor. That is, when the “first main electrode” is the source electrode, the “second main electrode” means the drain electrode. When the “first main electrode” is the emitter electrode, the “second main electrode” means the collector electrode. When the “first main electrode” is the anode electrode, the “second main electrode” means the cathode electrode.

A term “first external terminal” as recited in claims corresponds to one of a positive electrode terminal, a negative electrode terminal, an intermediate terminal, and an output terminal when the semiconductor device has a three-level configuration, and corresponds to one of the positive electrode terminal, the negative electrode terminal, and the output terminal when the semiconductor device has a two-level configuration. A term “second external terminal” as recited in claims corresponds to one of the positive electrode terminal, the negative electrode terminal, the intermediate terminal, and the output terminal other than that corresponding to the first external terminal when the semiconductor device has the three-level configuration, and corresponds to one of the positive electrode terminal, the negative electrode terminal, and the output terminal other than that corresponding to the first external terminal when the semiconductor device has the two-level configuration. A term “third external terminal” as recited in claims corresponds to one of the positive electrode terminal, the negative electrode terminal, the intermediate terminal, and the output terminal other than those corresponding to the first external terminal and the second external terminal when the semiconductor device has the three-level configuration, and corresponds to one of the positive electrode terminal, the negative electrode terminal, and the output terminal other than those corresponding to the first external terminal and the second external terminal when the semiconductor device has the two-level configuration. A term “fourth external terminal” as recited in claims corresponds to one of the positive electrode terminal, the negative electrode terminal, the intermediate terminal, and the output terminal other than those corresponding to the first external terminal to the third external terminal when the semiconductor device has the three-level configuration.

### First Embodiment

### <Circuit Configuration of Semiconductor Device>

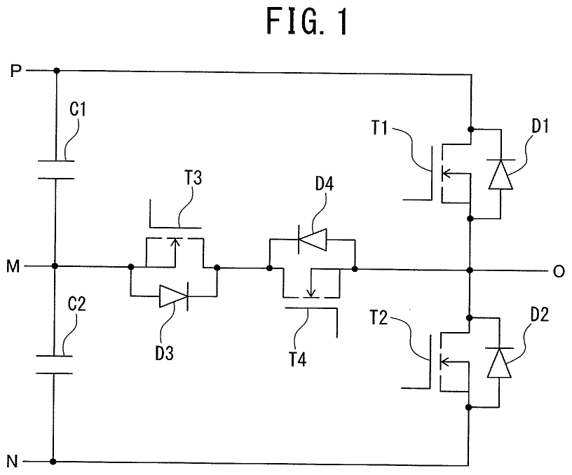

A semiconductor device according to a first embodiment is illustrated below with a power semiconductor module implementing a circuit for a single phase (a three-level circuit) of a three-level power conversion device (a three-level inverter). FIG. 1 illustrates an example of an equivalent circuit of the semiconductor device according to the first embodiment. As illustrated in FIG. 1, the semiconductor device according to the first embodiment implements a three-level circuit, and includes a positive electrode terminal P that is an input terminal, a negative electrode terminal N that is an input terminal, an intermediate terminal M that is an input terminal, and an output terminal O.

The positive electrode terminal P is connected to a drain of a transistor T1. A source of the transistor T1 is connected to the output terminal O and a drain of a transistor T2. A source of the transistor T2 is connected to the negative electrode terminal N.

The intermediate terminal M is connected to a source of a transistor T3. A drain of the transistor T3 is connected to a drain of a transistor T4. A source of the transistor T4 is connected to the source of the transistor T1 and the drain of the transistor T2.

The transistors T1 to T4 are internally provided with body diodes D1 to D4, respectively, each serving as a freewheeling diode (FWD) connected in antiparallel. A capacitor C1 is connected between the positive electrode terminal P and the intermediate terminal M. A capacitor C2 is connected between the intermediate terminal M and the negative electrode terminal N.

### <Structure of Semiconductor Device>

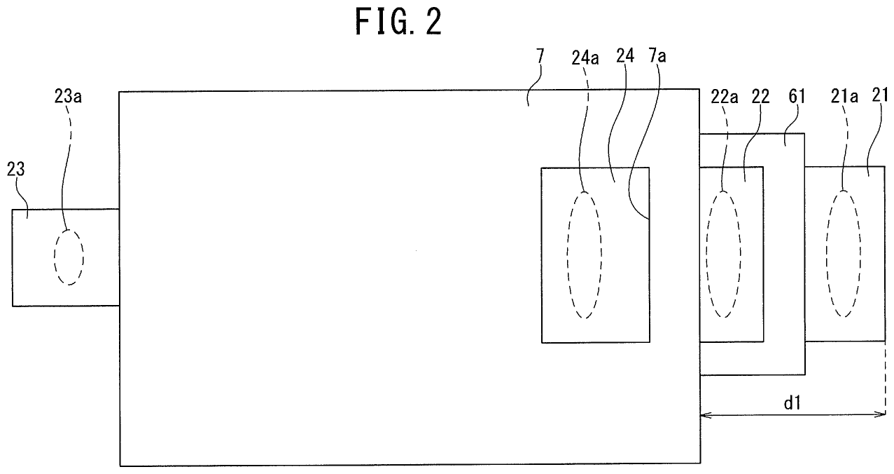

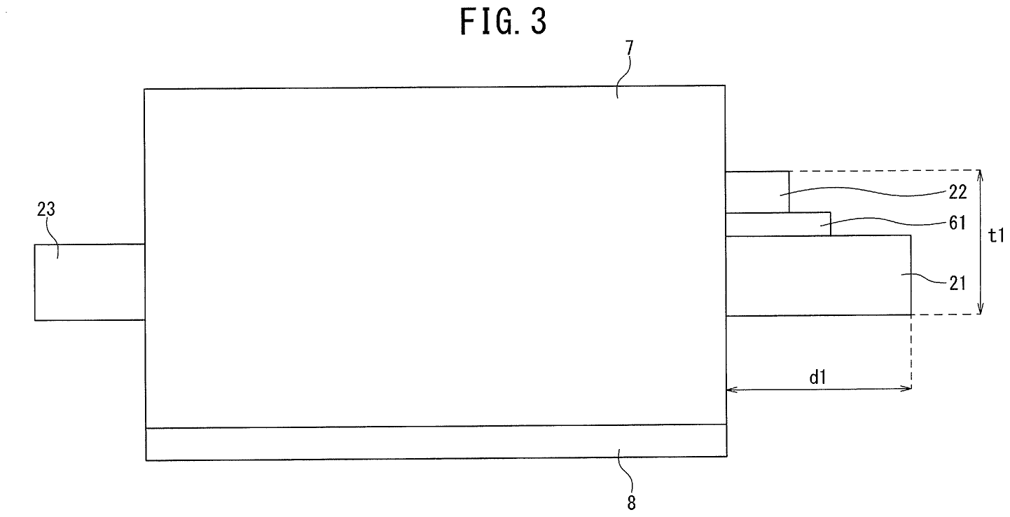

FIG. 2 is a plan view (a top view) of the semiconductor device according to the first embodiment, and FIG. 3 is a side view of the semiconductor device according to the first embodiment.

As illustrated in FIG. 2 and FIG. 3, the semiconductor device according to the first embodiment includes a sealing resin 7 having a substantially cuboidal shape, a positive electrode terminal (an external terminal) 21, a negative electrode terminal (an external terminal) 22, and an output terminal (an external terminal) 23 each exposed on side surfaces of the sealing resin 7, an intermediate terminal (an external terminal) 24 exposed on a top surface of the sealing resin 7, and a cooling plate 8 arranged on the bottom surface side of the sealing resin 7. The positive electrode terminal 21, the negative electrode terminal 22, the output terminal 23, and the intermediate terminal 24 respectively correspond to the positive electrode terminal P, the negative electrode terminal N, the output terminal O, and the intermediate terminal M illustrated in FIG. 1.

The positive electrode terminal 21 projects from the side surface of the sealing resin 7 and extends in one direction. The positive electrode terminal 21 includes a bonding region 21a to which an external circuit such as the capacitor C1 illustrated in FIG. 1 can be bonded by laser welding, for example. The bonding region 21a may be provided with a screw hole so as to be attached to the external circuit by screw fastening.

The negative electrode terminal 22 is arranged over the positive electrode terminal 21 with a plate-like (sheet-like) insulating member (insulating sheet) 61 interposed. The negative electrode terminal 22 projects from the side surface of the sealing resin 7 on the same side on which the positive electrode terminal 21 projects so as to extend in the direction substantially parallel to the extending direction of the positive electrode terminal 21. The negative electrode terminal 22 includes a bonding region 22a to which an external circuit such as the capacitor C2 illustrated in FIG. 1 can be bonded by laser welding, for example. The bonding region 22a may be provided with a screw hole so as to be attached to the external circuit by screw fastening.

The intermediate terminal 24 is exposed to an opening 7a provided on the top surface of the sealing resin 7. The intermediate terminal 24 includes a bonding region 24a to which the external circuits such as the capacitors C1 and C2 illustrated in FIG. 1 can be bonded by laser welding, for example. The bonding region 24a may be provided with screw holes so as to be attached to the external circuits by screw fastening.

The output terminal 23 projects from the side surface of the sealing resin 7 on the opposite side of the positive electrode terminal 21 and the negative electrode terminal 22 so as to extend in the direction opposite to the extending direction of the positive electrode terminal 21 and the negative electrode terminal 22. The output terminal 23 includes a bonding region 23a, as schematically indicated by the broken line, to which an external circuit such as a load can be bonded by laser welding, for example. The bonding region 23a may be provided with a screw hole so as to be attached to the external circuit by screw fastening.

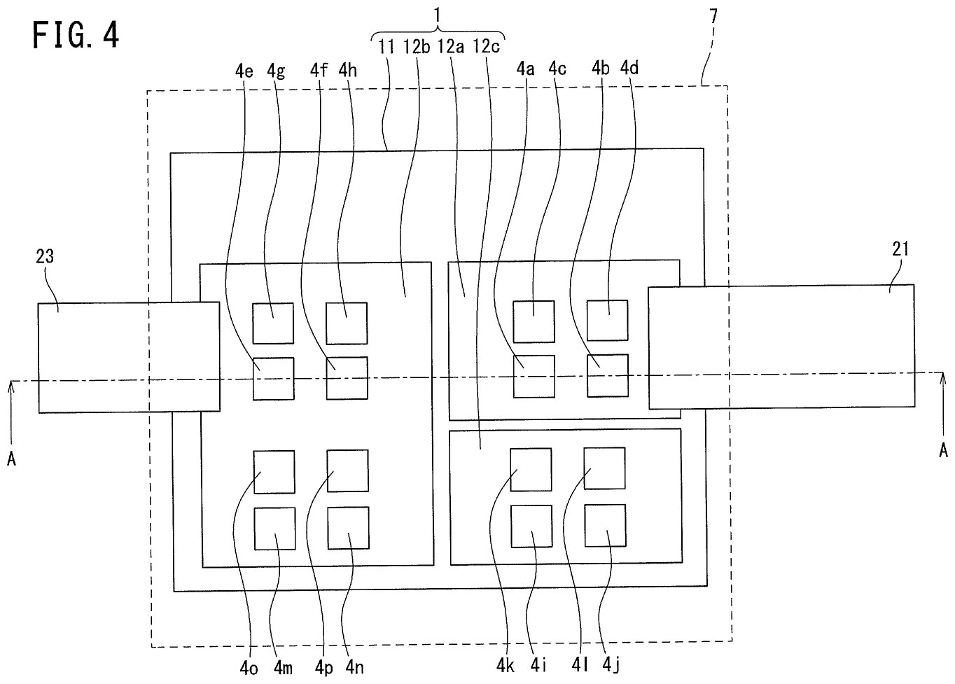

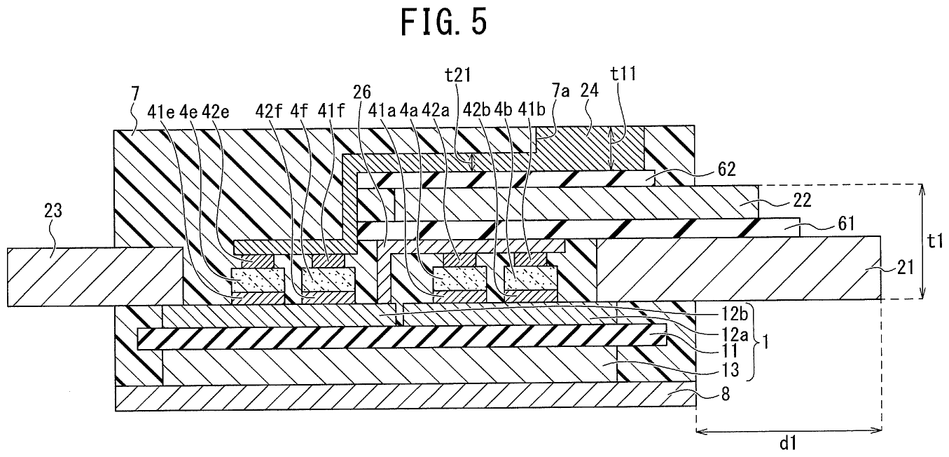

FIG. 4 is a plan view (a top view) of a structure inside the sealing resin 7 illustrated in FIG. 1 and FIG. 2. FIG. 4 schematically indicates the sealing resin 7 by the broken line, while omitting the illustration of the negative electrode terminal 22, the intermediate terminal 24, the insulating member 61, and the cooling plate 8 illustrated in FIG. 2 and FIG. 3. FIG. 5 is a cross-sectional view as viewed from direction A-A in FIG. 4, including the negative electrode terminal 22, the intermediate terminal 24, the insulating member 61, and the cooling plate 8 illustrated in FIG. 2 and FIG. 3.

As illustrated in FIG. 4 and FIG. 5, the semiconductor device according to the first embodiment includes the cooling plate (a base) 8, an insulated circuit substrate 1 provided on the cooling plate 8, and power semiconductor chips 4a to 4p each serving as a power semiconductor element provided on the insulated circuit substrate 1.

The cooling plate 8 is bonded to the bottom surface of the insulated circuit substrate 1 via solder, sintered material, or thermal compound, for example. The cooling plate 8 includes copper (Cu), aluminum (Al), composite material (AlSiC) of Al and silicon carbide (SiC), and composite material (MgSiC) of magnesium (Mg) and silicon carbide (SiC), for example. The cooling plate 8 is not necessarily provided on the bottom surface of the insulated circuit substrate 1 so as to lead the bottom surface of the insulated circuit substrate 1 to be exposed on the bottom surface of the sealing resin 7. Alternatively, a cooling fin may be provided, instead of the cooling plate 8, on the bottom surface side of the insulated circuit substrate 1.

The insulated circuit substrate 1 may be a direct copper bonded (DCB) substrate or an active metal brazed (AMB) substrate, for example. The insulated circuit substrate 1 includes an insulating plate 11, conductive plates (conductive foils) 12a to 12c provided on the top surface side of the insulating plate 11, and a heat-releasing plate (a conductive foil) 13 provided on the bottom surface side of the insulating plate 11.

The insulating plate 11 as used herein can be a ceramic plate mainly including aluminum oxide (Al₂O₃), aluminum nitride (AlN), silicon nitride (Si₃N₄), or boron nitride (BN), or a resin insulating layer including polymer material, for example. The heat-releasing plate 13 is not necessarily provided on the bottom surface side of the insulating plate 11 when the insulating plate 11 is the resin insulating layer. The conductive plates 12a to 12c and the heat-releasing plate 13 each include copper (Cu) and aluminum (Al), for example. The planar pattern, the number, and the arranged positions of the conductive plates 12a to 12c may be determined as appropriate.

The semiconductor chips 4a to 4d illustrated in FIG. 4 and FIG. 5 correspond to the transistor T1 and the body diode D1 illustrated in FIG. 1. The semiconductor chips 4e to 4h illustrated in FIG. 4 and FIG. 5 correspond to the transistor T2 and the body diode D2 illustrated in FIG. 1. The semiconductor chips 4i to 4l illustrated in FIG. 4 and FIG. 5 correspond to the transistor T3 and the body diode D3 illustrated in FIG. 1. The semiconductor chips 4m to 4p illustrated in FIG. 4 and FIG. 5 correspond to the transistor T4 and the body diode D4 illustrated in FIG. 1.

The semiconductor chips 4a to 4d are bonded onto the conductive plate 12a of the insulated circuit substrate 1 via bonding material (not illustrated) such as solder or sintered material. The semiconductor chips 4e to 4h and 4m to 4p are bonded onto the conductive plate 12b of the insulated circuit substrate 1 via bonding material (not illustrated) such as solder or sintered material. The semiconductor chips 4i to 4l are bonded onto the conductive plate 12c of the insulated circuit substrate 1 via bonding material (not illustrated) such as solder or sintered material.

The first embodiment is illustrated with the case in which the semiconductor chips 4a to 4p are each a metal-oxide-semiconductor field-effect-transistor (MOSFET). The semiconductor chips 4a to 4p may each be an insulated gate bipolar transistor (IGBT), a thyristor such as a static induction (SI) thyristor and a gate turn-off (GTO) thyristor, or a diode, for example. The semiconductor chips 4a to 4p are each made of a semiconductor substrate including material such as silicon (Si), silicon carbide (SIC), gallium nitride (GaN), and gallium oxide (Ga₂O₃). The arranged positions and the number of the semiconductor chips 4a to 4p may be determined as appropriate.

As illustrated in FIG. 5, the semiconductor chip 4a includes a first main electrode (a drain electrode) 41a provided on the bottom surface side, and a second main electrode (a source electrode) 42a and a gate electrode (not illustrated) provided on the top surface side. The semiconductor chip 4b includes a drain electrode 41b provided on the bottom surface side, and a source electrode 42b and a gate electrode (not illustrated) provided on the top surface side.

The conductive plate 12a of the insulated circuit substrate 1 is bonded to the drain electrodes 41a and 41b of the semiconductor chips 4a and 4b via bonding material such as solder or sintered material. One end of a lead frame 26 is bonded to the source electrodes 42a and 42b of the semiconductor chips 4a and 4b via bonding material (not illustrated) such as solder or sintered material. The conductive plate 12b of the insulated circuit substrate 1 is bonded to the other end of the lead frame 26 via bonding material (not illustrated) such as solder or sintered material. Control terminals (not illustrated) are electrically connected to the gate electrodes of the semiconductor chips 4a and 4b via bonding wires (not illustrated). Control signals are applied to the gate electrodes of the semiconductor chips 4a and 4b through the control terminals so as to control ON-OFF states of current flowing between the drain electrodes 41a and 41b and the source electrodes 42a and 42b of the semiconductor chips 4a and 4b.

The semiconductor chip 4e includes a drain electrode 41e provided on the bottom surface side, and a source electrode 42e and a gate electrode (not illustrated) provided on the top surface side. The semiconductor chip 4f includes a drain electrode 41f provided on the bottom surface side, and a source electrode 42f and a gate electrode (not illustrated) provided on the top surface side.

The conductive plate 12b of the insulated circuit substrate 1 is bonded to the drain electrodes 41e and 41f of the semiconductor chips 4e and 4f via bonding material (not illustrated) such as solder or sintered material. The intermediate terminal 24 is bonded to the source electrodes 42e and 42f of the semiconductor chips 4e and 4f via bonding material (not illustrated) such as solder or sintered material. Control terminals (not illustrated) are electrically connected to the gate electrodes of the semiconductor chips 4e and 4f via bonding wires (not illustrated). Control signals are applied to the gate electrodes of the semiconductor chips 4e and 4f through the control terminals so as to control ON-OFF states of current flowing between the drain electrodes 41e and 41f and the source electrodes 42e and 42f of the semiconductor chips 4e and 4f.

The semiconductor chips 4c, 4d, and 4g to 4p illustrated in FIG. 4 also include the source electrodes and the gate electrodes on the top surface side, and include the drain electrodes on the bottom surface side, in the same manner as the semiconductor chips 4a, 4b, 4e, and 4f illustrated in FIG. 5.

The positive electrode terminal 21, the negative electrode terminal 22, the output terminal 23, and the intermediate terminal 24 illustrated in FIG. 4 and FIG. 5 are electrically connected to the respective semiconductor chips 4a to 4p. Examples of material used for the positive electrode terminal 21, the negative electrode terminal 22, the output terminal 23, and the intermediate terminal 24 include copper (Cu), a Cu alloy, aluminum (Al), and an Al alloy. The thickness of each of the positive electrode terminal 21, the negative electrode terminal 22, the output terminal 23, and the intermediate terminal 24 depends on a rated current or a rated voltage, but is set in a range of 0.8 millimeters or greater and 2 millimeters or smaller, for example. The respective thicknesses of the positive electrode terminal 21, the negative electrode terminal 22, the output terminal 23, and the intermediate terminal 24 may be either the same or different from each other. The respective widths of the positive electrode terminal 21, the negative electrode terminal 22, the output terminal 23, and the intermediate terminal 24 may be either the same or different from each other.

The positive electrode terminal 21 has a flat plate-like shape. The positive electrode terminal 21 is bonded to the conductive plate 12a of the insulated circuit substrate 1 by laser welding, for example. The positive electrode terminal 21 may be bonded to the conductive plate 12a of the insulated circuit substrate 1 via a conductive member such as a copper block or a lead frame, or may have a part bent into an L-like shape or a Z-like shape so as to be attached to the conductive plate 12a of the insulated circuit substrate 1. The positive electrode terminal 21 is electrically connected to the drain electrodes 41a and 41b on the lower side of the semiconductor chips 4a and 4b. The positive electrode terminal 21 is also electrically connected to the drain electrodes on the lower side of the semiconductor chips 4c and 4d illustrated in FIG. 4. As illustrated in FIG. 2 to FIG. 5, a part of the positive electrode terminal 21 projects from the side surface of the sealing resin 7 and extends in one direction.

As illustrated in the cross-sectional view of FIG. 5, the negative electrode terminal 22 has a flat plate-like shape. The negative electrode terminal 22 is bonded to the conductive plate 12c of the insulated circuit substrate 1 illustrated in FIG. 4 by laser welding, for example. The negative electrode terminal 22 may be bonded to the conductive plate 12c of the insulated circuit substrate 1 via a conductive member such as a copper block or a lead frame, or may have a part bent into an L-like shape or a Z-like shape so as to be attached to the conductive plate 12c of the insulated circuit substrate 1. The negative electrode terminal 22 is electrically connected to the respective drain electrodes provided on the bottom surface side of the semiconductor chips 4i to 4l.

As illustrated in FIG. 2, FIG. 3, and FIG. 5, a part of the negative electrode terminal 22 projects from the side surface of the sealing resin 7 on the same side as the positive electrode terminal 21 so as to extend in the direction substantially parallel to the extending direction of the positive electrode terminal 21. A length of the part of the negative electrode terminal 22 projecting from the sealing resin 7 is shorter than that of the part of the insulating member 61 extending from the sealing resin 7. The length of the part of the insulating member 61 extending from the sealing resin 7 is shorter than that of the part of the positive electrode terminal 21 projecting from the sealing resin 7. The respective end parts of the negative electrode terminal 22, the insulating member 61, and the positive electrode terminal 21 are arranged in a stepped manner.

A large amount of current exceeding several hundreds of amperes flows through the positive electrode terminal 21, the negative electrode terminal 22, the output terminal 23, and the intermediate terminal 24. A wiring inductance (L) needs to be reduced so as to suppress a surge voltage (V=L×di/dt), since the surge voltage is caused by an influence of the wiring inductance upon the turn ON/OFF operation of the current to result in damage to the semiconductor chips 4a to 4p if the surge voltage exceeds a breakdown voltage of the semiconductor chips 4a to 4p. While an increase in thickness and a decrease in length of the wire or a division of a plurality of current paths arranged in parallel is effective for reducing the inductance, an increase of influence of mutual electromagnetic induction to reduce an apparent inductance is effective such that the respective current paths are arranged close to each other (laminated) so as to be directed in the directions opposite to each other in both ways in order to reduce the size.

To deal with this, as illustrated in FIG. 2, FIG. 3, and FIG. 5, a part of the positive electrode terminal 21 and a part of the negative electrode terminal 22 are deposited close to each other (laminated) so as to overlap substantially parallel to each other with the insulating member 61 interposed from the inside to the outside of the sealing resin 7. The insulating member 61 has a constant thickness so that a part of the positive electrode terminal 21 and a part of the negative electrode terminal 22 arranged substantially in parallel are separated from each other at a predetermined distance. The thickness of the insulating member 61 is not necessarily constant. The wiring inductance between the positive electrode terminal 21 and the negative electrode terminal 22 can be reduced since the current flows in the current paths in the directions opposite to each other in both ways in the parts of the positive electrode terminal 21 and the negative electrode terminal 22 overlapping with each other. The arrangement of the positive electrode terminal 21, the intermediate terminal 24, and the negative electrode terminal 22 deposited in this order can further reduce the wiring inductance between the positive electrode terminal 21 and the intermediate terminal 24 and the wiring inductance between the intermediate terminal 24 and the negative electrode terminal 23.

As illustrated in FIG. 5, the intermediate terminal 24 has parts bent into a Z-like shape so as to be bonded to the respective source electrodes on the top surface side of the semiconductor chips 4e and 4f via bonding material such as solder or sintered material. The intermediate terminal 24 does not necessarily have the bent parts, and may be electrically connected to the respective source electrodes on the top surface side of the semiconductor chips 4e and 4f via a conductive member such as a copper block or a lead frame. The intermediate terminal 24 is also electrically connected to the respective source electrodes on the top surface side of the semiconductor chips 4g and 4h illustrated in FIG. 4.

As illustrated in FIG. 5, a part of the negative electrode terminal 22 and a part of the intermediate terminal 24 are deposited close to each other (laminated) so as to overlap with each other substantially in parallel with a plate-like (sheet-like) insulating member (an insulating sheet) 62 interposed inside the sealing resin 7. The insulating member 62 has a constant thickness so that a part of the negative electrode terminal 22 and a part of the intermediate terminal 24 arranged substantially in parallel are separated from each other at a predetermined distance. The thickness of the insulating member 62 is not necessarily constant. The wiring inductance between the negative electrode terminal 22 and the intermediate terminal 24 can be reduced since the current flows in the current paths in the directions opposite to each other in both ways in the parts of the negative electrode terminal 22 and the intermediate terminal 24 overlapping with each other.

The respective insulating members 61 and 62 as used herein can be an insulating sheet or can include insulating material having high insulating and heat-resistance properties such as polyimide or polyamide. The respective insulating members 61 and 62 may include epoxy resin or polyphenylene sulfide (PPS) resin instead. When the resin material is used for the respective insulating members 61 and 62, a plate-like (sheet-like) resin material may be interposed, or the respective terminals such as the positive electrode terminal 21, the negative electrode terminal 22, and the intermediate terminal 24 may be prepared as an integrated component together with resin material by primary molding so as to be deposited on the respective semiconductor chips 4a to 4p. The respective insulating members 61 and 62 may have a smaller thickness than each of the positive electrode terminal 21, the negative electrode terminal 22, and the intermediate terminal 24. The thickness of the respective insulating members 61 and 62 is in a range of 0.1 millimeters or greater and 1.0 millimeters or smaller, for example.

As illustrated in FIG. 2 and FIG. 5, a part of the intermediate terminal 24 is exposed to the opening 7a provided on the top surface of the sealing resin 7. The top surface of the intermediate terminal 24 exposed to the opening 7a has the same plane as the top surface of the sealing resin 7. A thickness t11 of the intermediate terminal 24 at the part at which the top surface is exposed is greater than a thickness t12 of the other part of the intermediate terminal 24 not exposed. The intermediate terminal 24 may be bent into a Z-like shape so as to be exposed to the opening 7a. The thickness of the intermediate terminal 24 at the part at which the top surface is exposed may be either the same as or smaller than the thickness of the other part of the intermediate terminal 24 not exposed.

As illustrated in FIG. 2 to FIG. 5, the output terminal 23 has a flat plate-like shape. The output terminal 23 is bonded to the conductive plate 12b of the insulated circuit substrate 1 by laser welding, for example. The output terminal 23 may be bonded to the conductive plate 12b of the insulated circuit substrate 1 via a conductive member such as a copper block or a lead frame, or may have a part bent into an L-like shape or a Z-like shape so as to be attached to the conductive plate 12b of the insulated circuit substrate 1.

The output terminal 23 is electrically connected to the source electrodes 42a and 42b on the upper side of the semiconductor chips 4a and 4b and the drain electrodes 41e and 41f on the lower side of the semiconductor chips 4e and 4f. The output terminal 23 is also electrically connected to the source electrodes on the upper side of the semiconductor chips 4c and 4d and the drain electrodes on the lower side of the semiconductor chips 4g, 4h, and 4m to 4p illustrated in FIG. 4. A part of the output terminal 23 projects from the side surface of the sealing resin 7 on the side opposite to the side surface from which the negative electrode terminal 22 and the positive electrode terminal 21 project so as to extend in the opposite direction of the negative electrode terminal 22 and the positive electrode terminal 21.

The sealing resin 7 seals the insulated circuit substrate 1 and the respective semiconductor chips 4a to 4p and the like. The sealing resin 7 as used herein can include resin having insulating properties such as thermosetting silicone gel or epoxy resin.

As described above, the semiconductor device according to the first embodiment has the configuration in which the three terminals of the positive electrode terminal 21, the negative electrode terminal 22, and the intermediate terminal 24 are deposited close to each other (laminated) with the respective insulating members 61 and 62 interposed, and two of the positive electrode terminal 21 and the negative electrode terminal 22 on the lower side project from the side surface of the sealing resin 7, while the other intermediate terminal 24 on the uppermost side is exposed on the top surface of the sealing resin 7. This configuration can decrease the distance d1 and the thickness t1 of the part of the positive electrode terminal 21 and the negative electrode terminal 22 projecting from the sealing resin 7, so as to achieve a reduction in the entire size, as compared with a case in which three of the positive electrode terminal 21, the negative electrode terminal 22, and the intermediate terminal 24 project from the same side surface of the sealing resin 7.

### <Method of Manufacturing Semiconductor Device>

An example of a method of manufacturing the semiconductor device according to the first embodiment is described below.

The heat-releasing plate 13 of the insulated circuit substrate 1 is bonded onto the cooling plate 8 illustrated in FIG. 4 and FIG. 5 via bonding material such as sintered material or thermal compound. Further, the semiconductor chips 4a to 4p are bonded onto the respective conductive plates 12a to 12c of the insulated circuit substrate 1 via bonding material such as solder or sintered material.

Next, the positive electrode terminal 21, the negative electrode terminal 22, the output terminal 23, the intermediate terminal 24, and the lead frame 26 are bonded onto the conductive plates 12a to 12c of the insulated circuit substrate 1 and the semiconductor chips 4a to 4p via bonding material such as solder or sintered material. The positive electrode terminal 21 and the negative electrode terminal 22 are deposited close to each other with the insulating member 61 interposed, and the negative electrode terminal 22 and the intermediate terminal 24 are deposited close to each other with the insulating member 62 interposed.

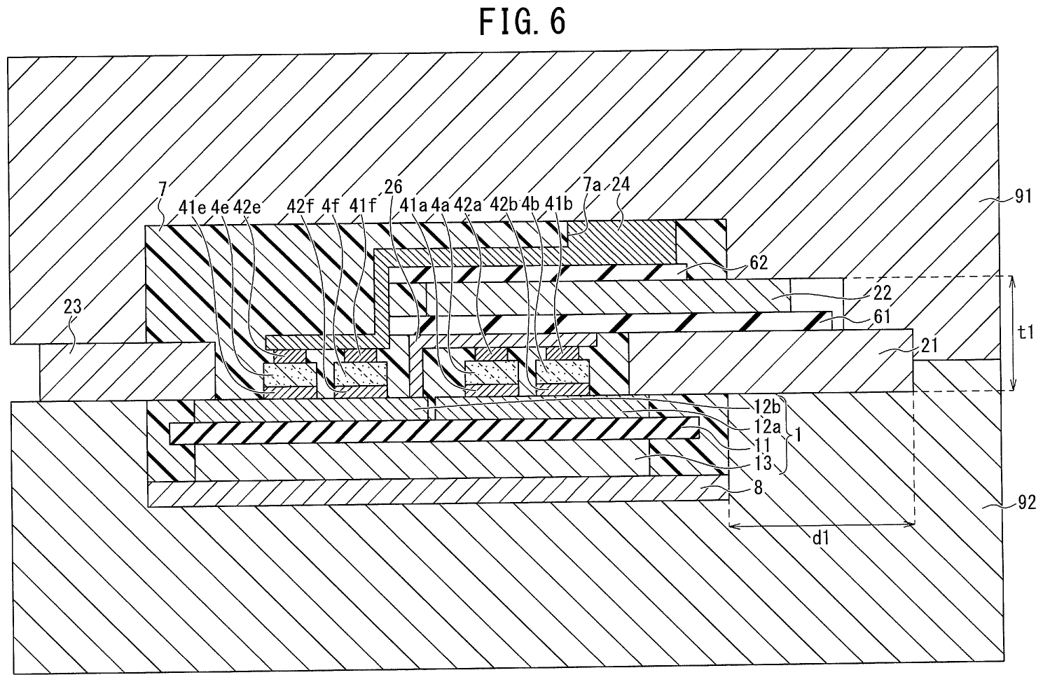

Next, the insulated circuit substrate 1, the semiconductor chips 4a to 4p, the positive electrode terminal 21, the negative electrode terminal 22, the output terminal 23, the intermediate terminal 24, the lead frame 26, and the insulating member 61 and the like are fixed (chucked) from the respective upper and lower sides with metal dies 91 and 92 (refer to FIG. 6). The top surface of the part of the intermediate terminal 24 to be exposed to the sealing resin 7 at this point is in contact with the metal die 91. The resin is then injected into the space inside the metal dies 91 and 92 so as to execute transfer molding. This step forms the sealing resin 7 as illustrated in FIG. 6, so as to complete the semiconductor device according to the first embodiment.

### First Comparative Example

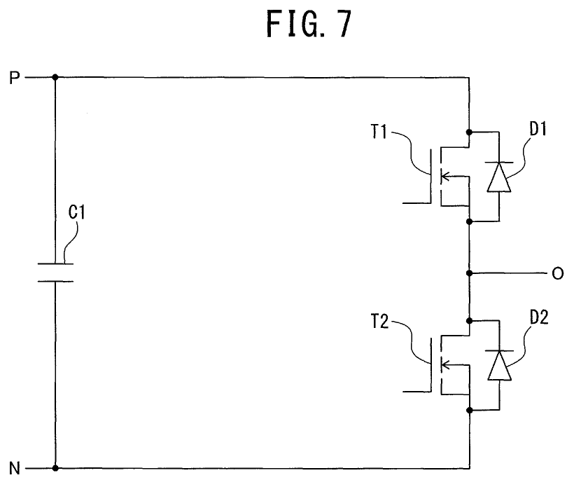

FIG. 7 is a diagram illustrating an example of an equivalent circuit of a semiconductor device of a first comparative example. The semiconductor device of the first comparative example differs from the semiconductor device according to the first embodiment having the three-level circuit configuration illustrated in FIG. 1 in implementing a two-level circuit, as illustrated in FIG. 7. More particularly, the semiconductor device of the first comparative example differs from the semiconductor device according to the first embodiment illustrated in FIG. 1 in not including the intermediate terminal M, not including the capacitor C2 connected between the intermediate terminal M and the output terminal O, or not including the respective transistors T3 and T4 or the respective body diodes D3 and D4 connected between the intermediate terminal M and the output terminal O.

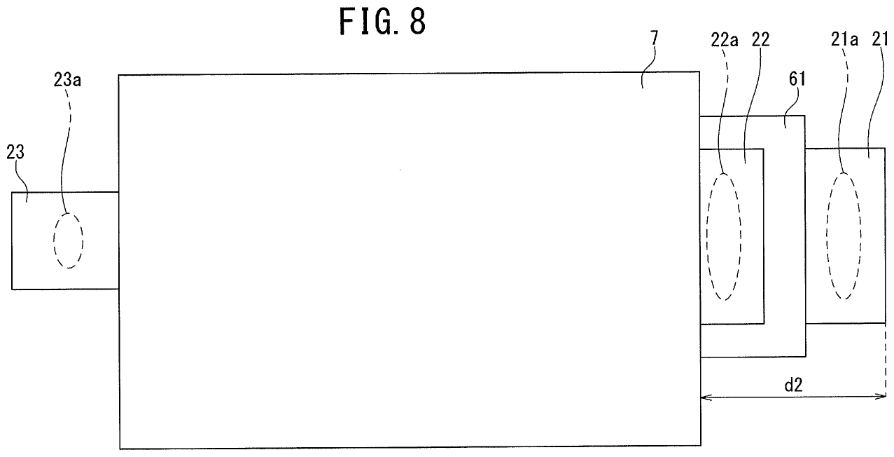

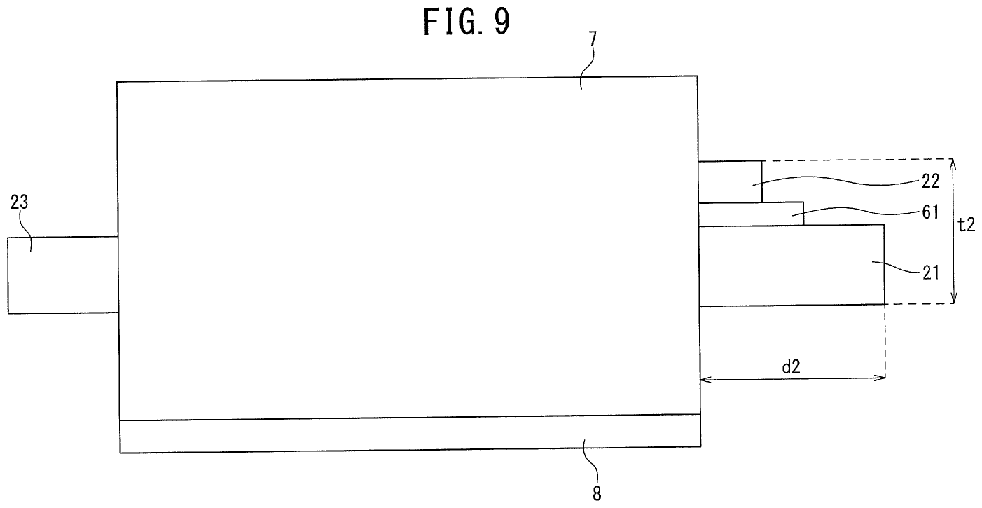

FIG. 8 is a plan view (a top view) of the semiconductor device of the first comparative example, and FIG. 9 is a side view of the semiconductor device of the first comparative example. As illustrated in FIG. 8 and FIG. 9, the semiconductor device of the first comparative example differs from the semiconductor device according to the first embodiment illustrated in FIG. 2 and FIG. 3 in that the intermediate terminal 24 is not provided while the negative electrode terminal 22 projects from the side surface of the sealing resin 7 with the top surface not provided with the opening 7a.

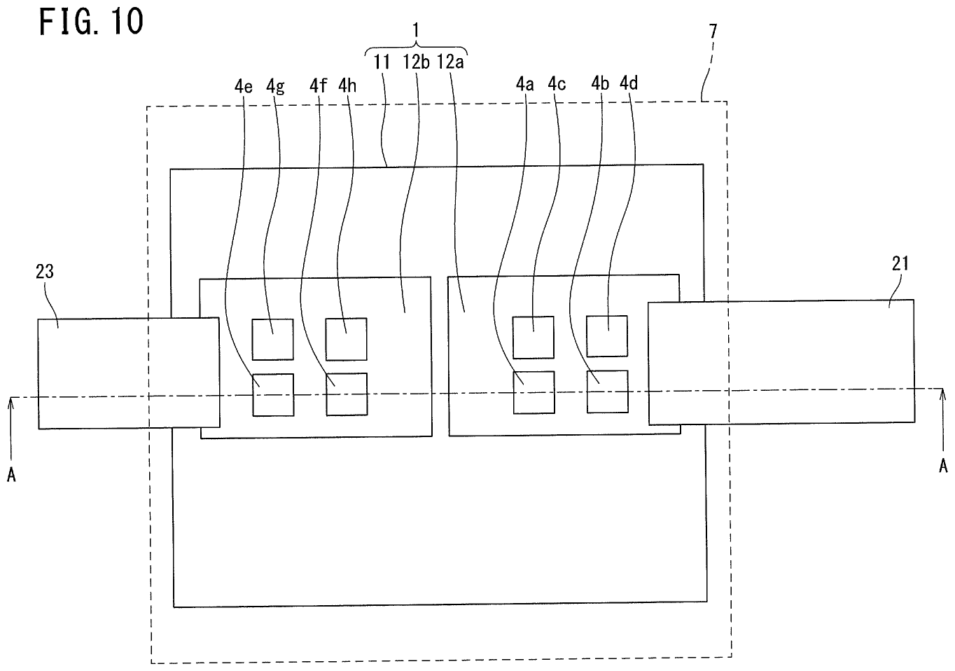

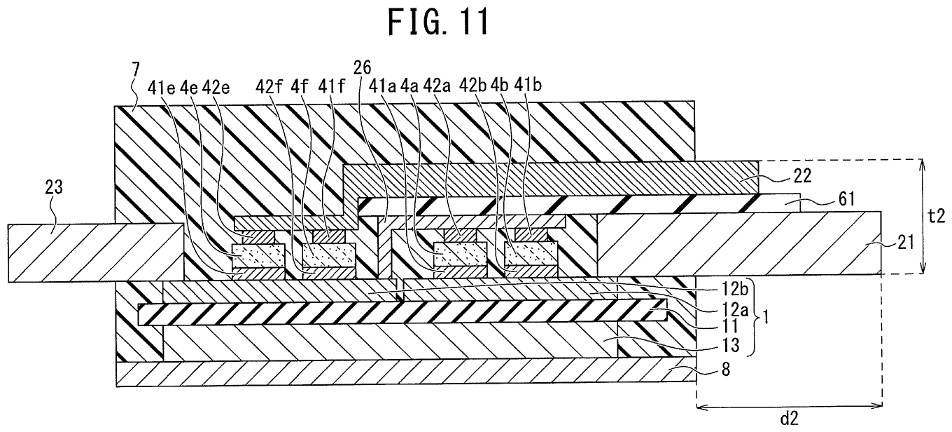

FIG. 10 is a plan view (a top view) of a structure inside the sealing resin 7 illustrated in FIG. 8 and FIG. 9. FIG. 10 schematically indicates the sealing resin 7 by the broken line, while omitting the illustration of the positive electrode terminal 21, the insulating member 61, and the cooling plate 8 illustrated in FIG. 8 and FIG. 9. FIG. 11 is a cross-sectional view as viewed from direction A-A in FIG. 10, including the negative electrode terminal 21, the insulating member 61, and the cooling plate 8 illustrated in FIG. 8 and FIG. 9.

As illustrated in FIG. 10 and FIG. 11, the semiconductor device of the first comparative example differs from the semiconductor device according to the first embodiment illustrated in FIG. 4 and FIG. 5 in that the conductive plate 12c and the semiconductor chips 4i to 4p are not provided on the top surface side of the insulated circuit substrate 1, and in that the positive electrode terminal 21 and the negative electrode terminal 22 are deposited close to each other (laminated) with the insulating member 61 interposed.

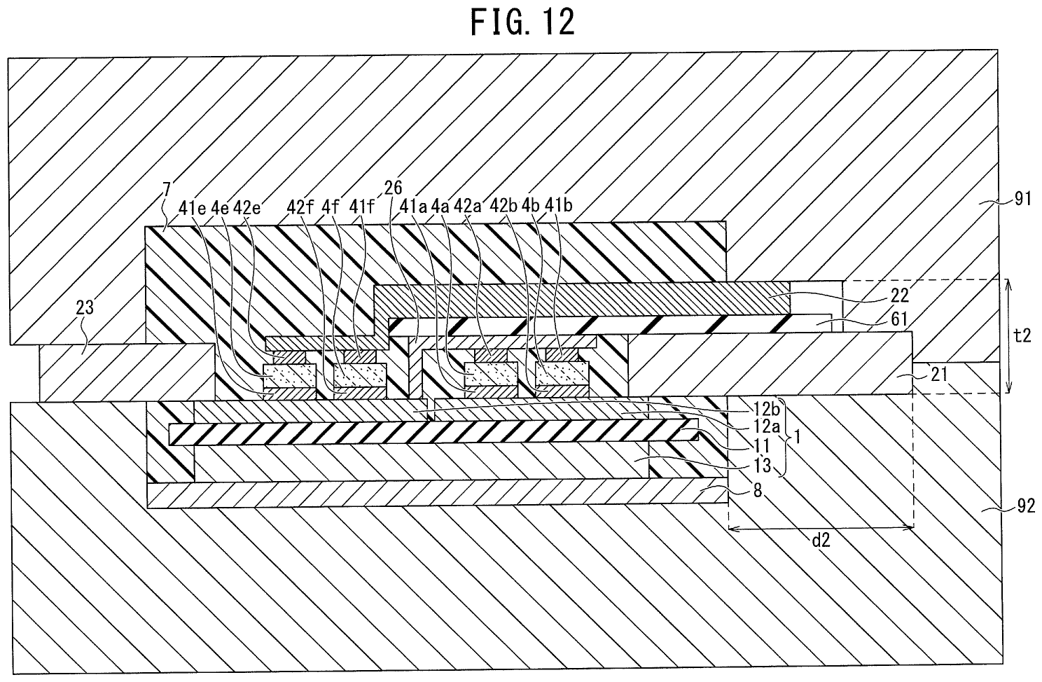

A method of manufacturing the semiconductor device of the first comparative example forms the sealing resin 7 by transfer molding by use of the metal dies 91 and 92, as illustrated in FIG. 12. The semiconductor device according to the first embodiment is manufactured such that the distance d1 and the thickness t1 of the part of the positive electrode terminal 21 and the negative electrode terminal 22 projecting from the sealing resin 7 illustrated in FIG. 6 are adjusted so as to conform to the distance d2 and the thickness t2 of the part of the positive electrode terminal 21 and the negative electrode terminal 22 projecting from the sealing resin 7 in the semiconductor device of the first comparative example illustrated in FIG. 12. The outline of the part projecting from the sealing resin 7 in the semiconductor device according to the first embodiment thus conforms to the outline of the part projecting from the sealing resin 7 in the semiconductor device of the first comparative example. This can use the common metal dies 91 and 92 for the transfer molding in both of the semiconductor device according to the first embodiment illustrated in FIG. 6 and the semiconductor device of the first comparative example illustrated in FIG. 12.

### Second Comparative Example

A semiconductor device of a second comparative example has the same configuration as the semiconductor device according to the first embodiment illustrated in FIG. 1 in implementing the three-level circuit.

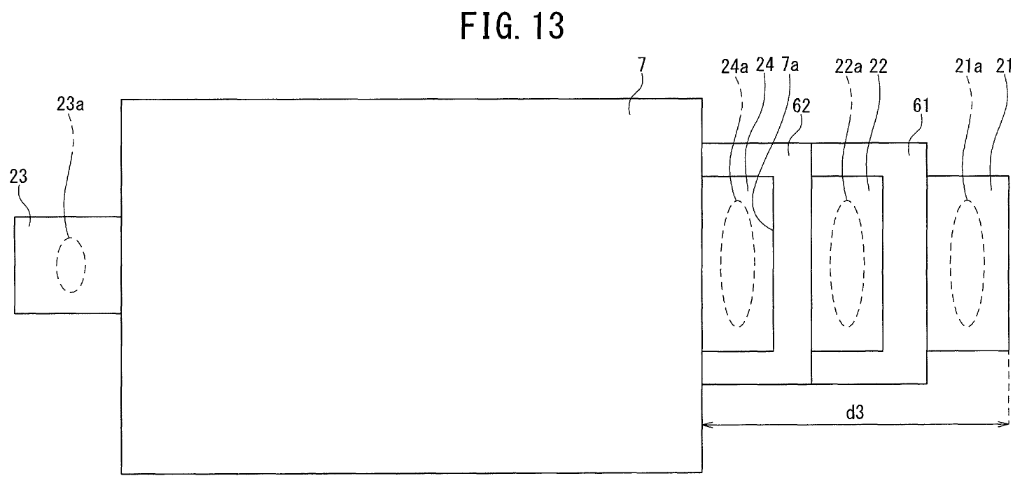

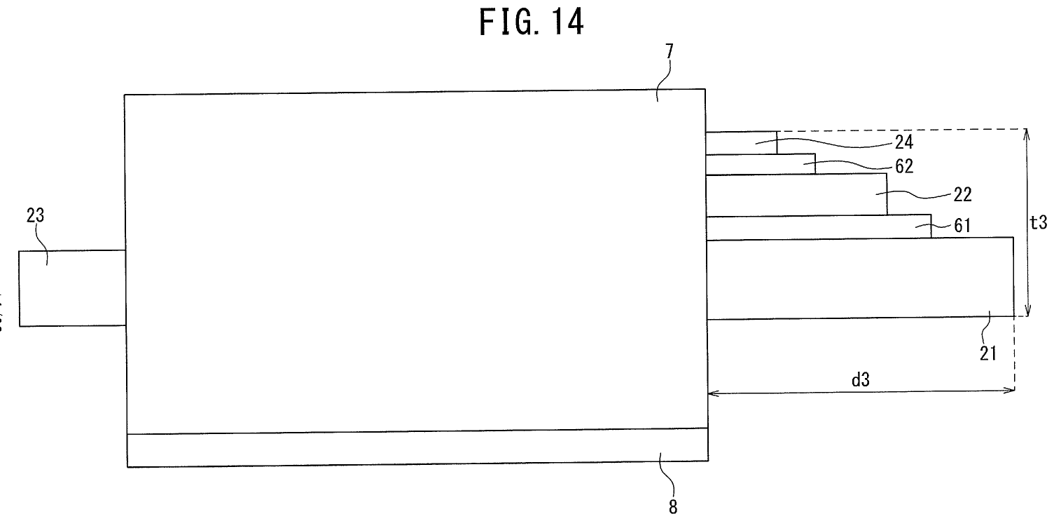

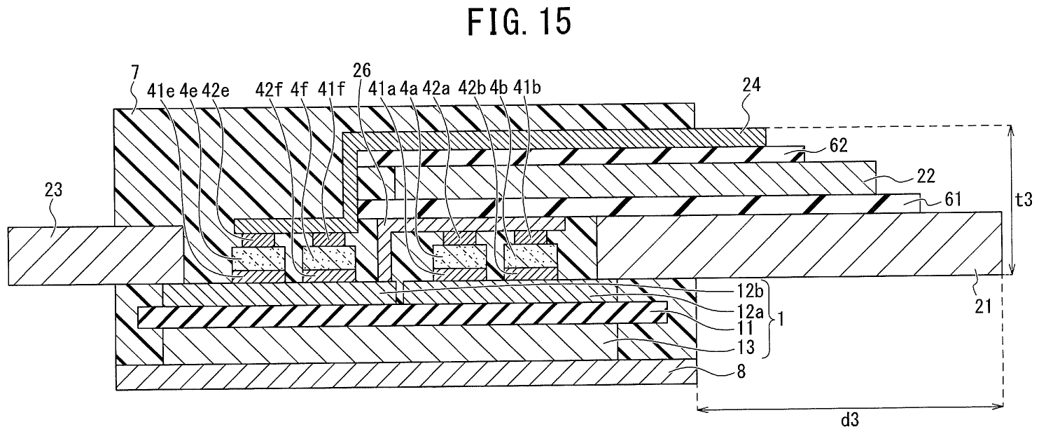

FIG. 13 is a plan view (a top view) of the semiconductor device of the second comparative example, FIG. 14 is a side view of the semiconductor device of the second comparative example, and FIG. 15 is a cross-sectional view of the semiconductor device of the second comparative example corresponding to the position illustrated in FIG. 5. As illustrated in FIG. 13 to FIG. 15, the semiconductor device of the second comparative example differs from the semiconductor device according to the first embodiment in that the three terminals of the positive electrode terminal 21, the negative electrode terminal 22, and the intermediate terminal 24 project from the same side surface of the sealing resin 7.

The configuration of the semiconductor device of the second comparative example inevitably increases the distance d3 and the thickness t3 of the part of the positive electrode terminal 21, the negative electrode terminal 22, and the intermediate terminal 24 projecting from the same side surface of the sealing resin 7, impeding a reduction in the entire size of the device.

The execution of resin molding upon manufacture without the outline and size changed can contribute to a standardization of components of the manufacturing device regardless of whether a two-level circuit or a three-level circuit is manufactured. The method of manufacturing the semiconductor device of the second comparative example, however, needs to change the shape of the metal dies, since the number of the terminals projecting from the same side surface of the sealing resin 7 is increased, and the distance d3 and the thickness t3 of the part of the positive electrode terminal 21, the negative electrode terminal 22, and the intermediate terminal 24 projecting from the sealing resin 7 are increased, which obstructs the outline of the metal dies 91 and 92 used for the transfer molding in the semiconductor device of the first comparative example illustrated in FIG. 12.

In contrast, the configuration of the semiconductor device according to the first embodiment can contribute to the standardization of the manufacturing components so as to use the common metal dies 91 and 92 for the transfer molding in each of the semiconductor device according to the first embodiment illustrated in FIG. 6 and the semiconductor device of the first comparative example illustrated in FIG. 12. This eliminates the problem of rearrangement or change of the metal dies during the manufacturing process, so as to suppress an increase in manufacturing cost of the metal dies or products accordingly.

### Second Embodiment

A semiconductor device according to a second embodiment differs from the semiconductor device according to the first embodiment having the three-level circuit configuration illustrated in FIG. 1 in implementing a two-level circuit, as in the case of the semiconductor device of the first comparative example illustrated in FIG. 7.

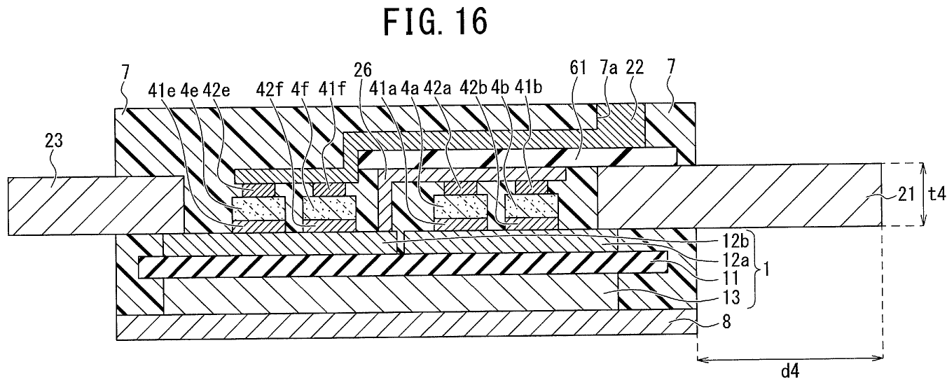

The plan view (the top view) of the semiconductor device according to the second embodiment is the same as the plan view (the top view) of the semiconductor device of the first comparative example illustrated in FIG. 10. FIG. 16 is a cross-sectional view of the semiconductor device according to the second embodiment corresponding to the position illustrated in FIG. 5 and FIG. 11.

As illustrated in FIG. 10 and FIG. 16, the semiconductor device according to the second embodiment differs from the semiconductor device according to the first embodiment in that the intermediate terminal 24 is eliminated and the conductive plate 12c and the semiconductor chips 4i to 4p are not provided on the top surface side of the insulated circuit substrate 1, and in that a part of the negative electrode terminal 22 is exposed to the opening 7a provided on the top surface of the sealing resin 7. The other configurations of the semiconductor device according to the second embodiment are substantially the same as those of the semiconductor device according to the first embodiment, and overlapping explanations are not repeated below.

As described above, the semiconductor device according to the second embodiment has the two-level circuit configuration including the positive electrode terminal 21 and the negative electrode terminal 22 deposited close to each other with the insulating member 61 interposed, in which the positive electrode terminal 21 on the lower side, which is one of the two terminals, projects from the side surface of the sealing resin 7, and the other negative electrode terminal 22 on the upper side is exposed on the top surface of the sealing resin 7. This configuration can decrease the distance d4 and the thickness t4 of the part of the positive electrode terminal 21 projecting from the sealing resin 7, so as to achieve a reduction in the entire size, as compared with a case in which both the positive electrode terminal 21 and the negative electrode terminal 22 project from the side surface of the sealing resin 7.

### Third Embodiment

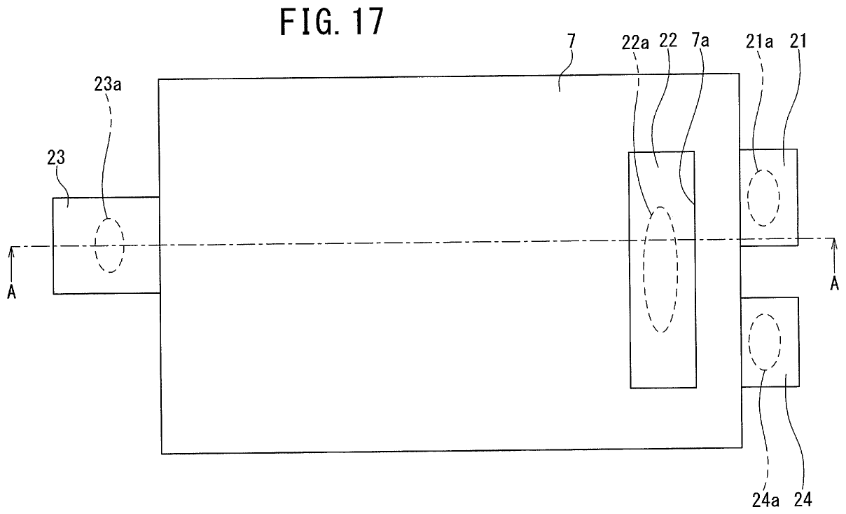

FIG. 17 is a plan view (a top view) illustrating a semiconductor device according to a third embodiment. As illustrated in FIG. 17, the semiconductor device according to the third embodiment differs from the semiconductor device according to the first embodiment illustrated in FIG. 2 in that the positive electrode terminal 21 and the intermediate terminal 24 projecting from the side surface of the sealing resin 7 do not overlap with each other but are arranged laterally next to each other in the horizontal direction. The negative electrode terminal 22 is exposed to the opening 7a provided on the top surface of the sealing resin 7.

The cross-sectional view as viewed from direction A-A in FIG. 17 is common to FIG. 16. As illustrated in FIG. 16, the positive electrode terminal 21 and the negative electrode terminal 22 are deposited close to each other with the insulating sheet 61 interposed inside the sealing resin 7. Although not illustrated, the intermediate terminal 24 and the negative electrode terminal 22 are also deposited close to each other with an insulating sheet interposed inside the sealing resin 7. The other configurations of the semiconductor device according to the third embodiment are substantially the same as those of the semiconductor device according to the first embodiment, and overlapping explanations are not repeated below.

As described above, the semiconductor device according to the third embodiment has the configuration in which the negative electrode terminal 22 is deposited close to the positive electrode terminal 21 and the intermediate terminal 24 (laminated together), in which the positive electrode terminal 21 and the intermediate terminal 24 on the lower side project from the side surface of the sealing resin 7, while the negative electrode terminal 22 on the upper side is exposed on the top surface of the sealing resin 7. This configuration can decrease the distance d4 and the thickness t4 of the part of each of the positive electrode terminal 21 and the intermediate terminal 24 projecting from the sealing resin 7 (refer to FIG. 16), so as to achieve a reduction in the entire size, as compared with a case in which three of the positive electrode terminal 21, the negative electrode terminal 22, and the intermediate terminal 24 project from the side surface of the sealing resin 7.

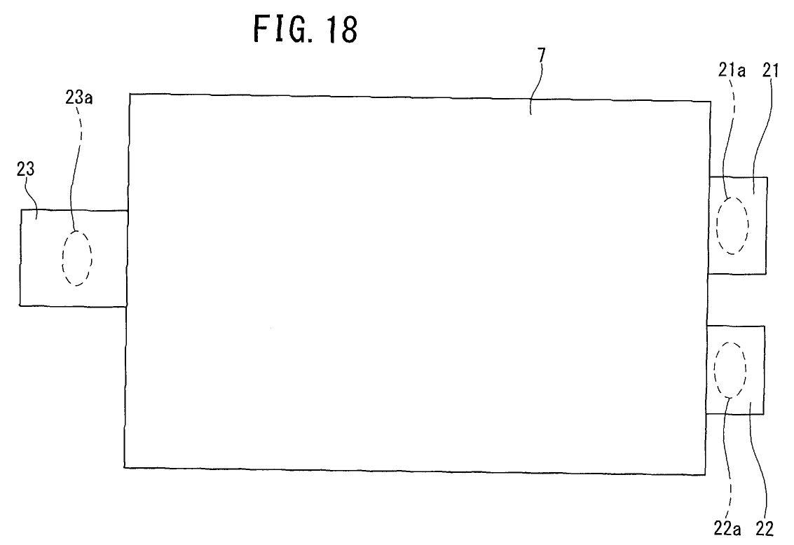

Further, the configuration of the semiconductor device according to the third embodiment can lead the outline illustrated in FIG. 17 to conform to that of a semiconductor device implementing a two-level circuit illustrated in FIG. 18. The semiconductor device having the two-level circuit configuration illustrated in FIG. 18 includes the positive electrode terminal 21 and the negative electrode terminal 22 not overlapping with each other but arranged laterally next to each other in the horizontal direction. This configuration can use the common metal dies for the transfer molding in each of the semiconductor device according to the third embodiment illustrated in FIG. 17 and the semiconductor device implementing the two-level circuit illustrated in FIG. 18. The common use of the metal dies eliminates the problem of rearrangement or change of the metal dies during the manufacturing process, so as to suppress an increase in manufacturing cost of metal dies or products accordingly.

### Fourth Embodiment

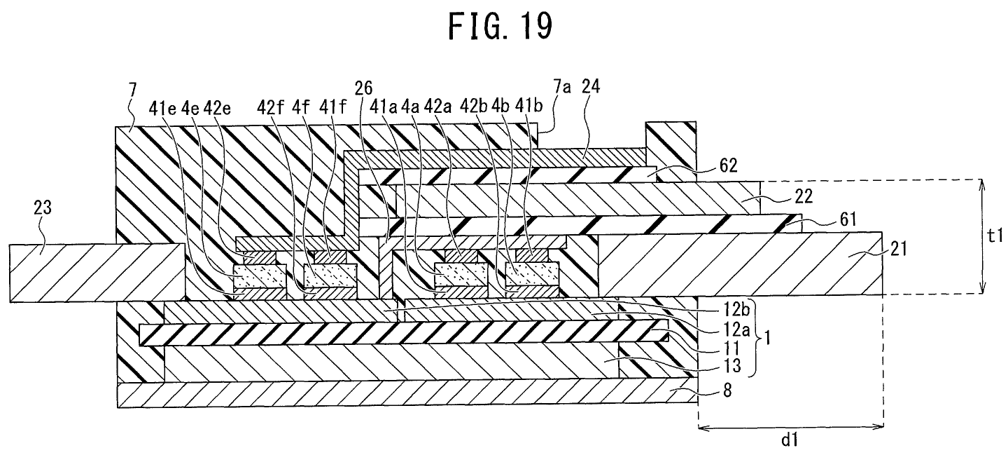

FIG. 19 is a cross-sectional view illustrating a semiconductor device according to a fourth embodiment corresponding to the position illustrated in FIG. 5. As illustrated in FIG. 19, the semiconductor device according to the fourth embodiment differs from the semiconductor device according to the first embodiment illustrated in FIG. 5 in that the top surface of the intermediate terminal 24 exposed on the top surface of the sealing resin 7 does not have the same plane as the top surface of the sealing resin 7 but is recessed downward from the top surface of the sealing resin 7.

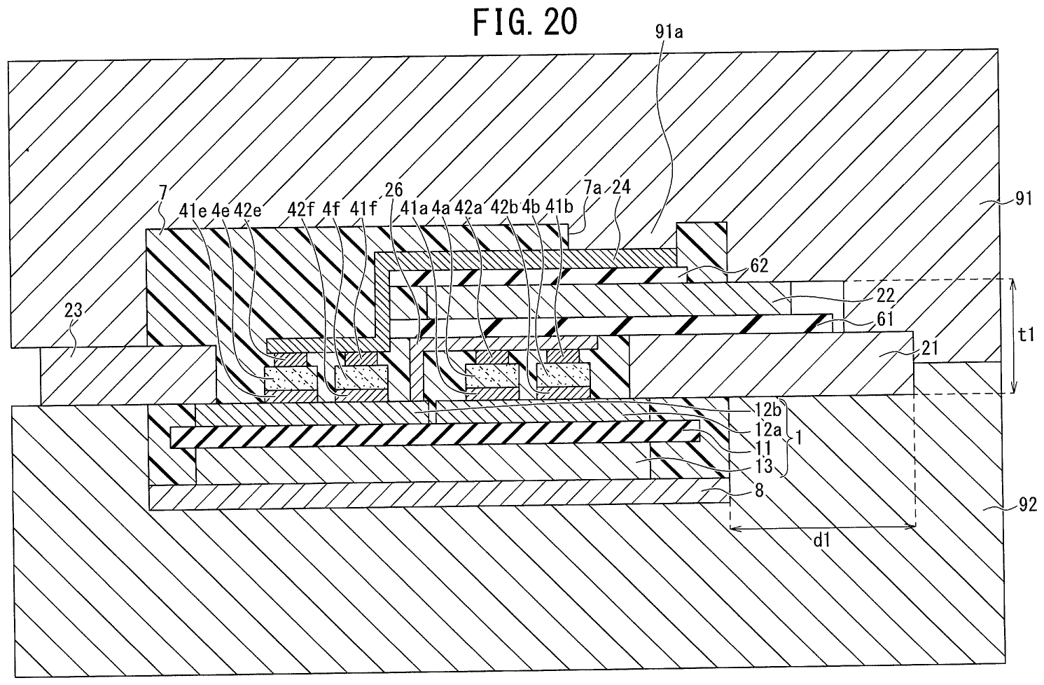

The transfer molding for the semiconductor device according to the fourth embodiment uses the metal die 91 provided with a projection 91a, as illustrated in FIG. 20. The execution of the transfer molding while a part of the intermediate terminal 24 to be exposed on the top surface of the sealing resin 7 is in contact with the projection 91a of the metal die 91 provides the opening 7a in the sealing resin 7. The other configurations of the semiconductor device according to the fourth embodiment are substantially the same as those of the semiconductor device according to the first embodiment, and overlapping explanations are not repeated below.

As described above, the semiconductor device according to the fourth embodiment has the configuration in which the three terminals of the positive electrode terminal 21, the negative electrode terminal 22, and the intermediate terminal 24 are deposited close to each other (laminated) with the respective insulating members 61 and 62 interposed, and two of the positive electrode terminal 21 and the negative electrode terminal 22 on the lower side project from the side surface of the sealing resin 7, while the other intermediate terminal 24 on the uppermost side is exposed on the top surface of the sealing resin 7. This configuration can decrease the distance d1 and the thickness t1 of the part of the positive electrode terminal 21 and the negative electrode terminal 22 projecting from the sealing resin 7, so as to achieve a reduction in the entire size, as compared with a case in which three of the positive electrode terminal 21, the negative electrode terminal 22, and the intermediate terminal 24 project from the side surface of the sealing resin 7. Further, the configuration in which the top surface of the intermediate terminal 24 is recessed downward from the top surface of the sealing resin 7 leads a conductive member (not illustrated), which is to be connected to the intermediate terminal 24, to be fitted into the recessed shape, so as to facilitate the mutual positioning.

### Fifth Embodiment

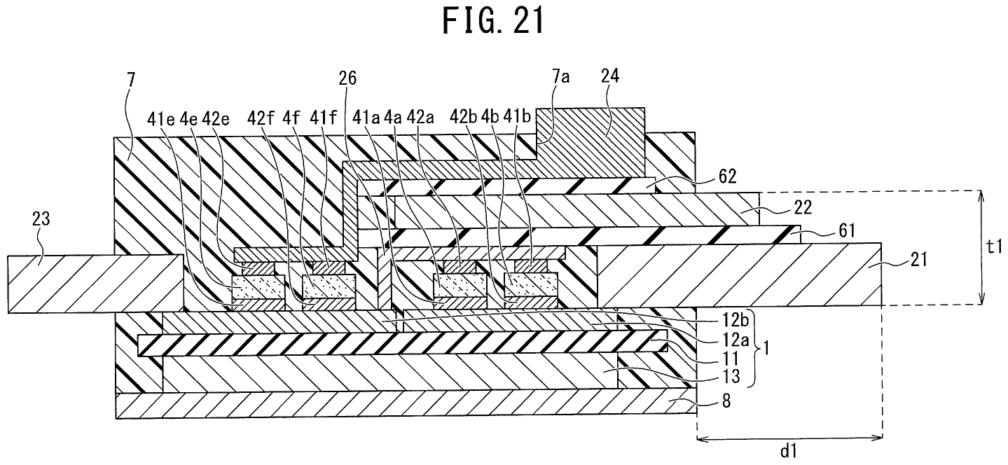

FIG. 21 is a cross-sectional view illustrating a semiconductor device according to a fifth embodiment corresponding to the position illustrated in FIG. 5. As illustrated in FIG. 21, the semiconductor device according to the fifth embodiment differs from the semiconductor device according to the first embodiment illustrated in FIG. 5 in that the top surface of the intermediate terminal 24 exposed on the top surface of the sealing resin 7 does not have the same plane as the top surface of the sealing resin 7 but projects upward from the top surface of the sealing resin 7.

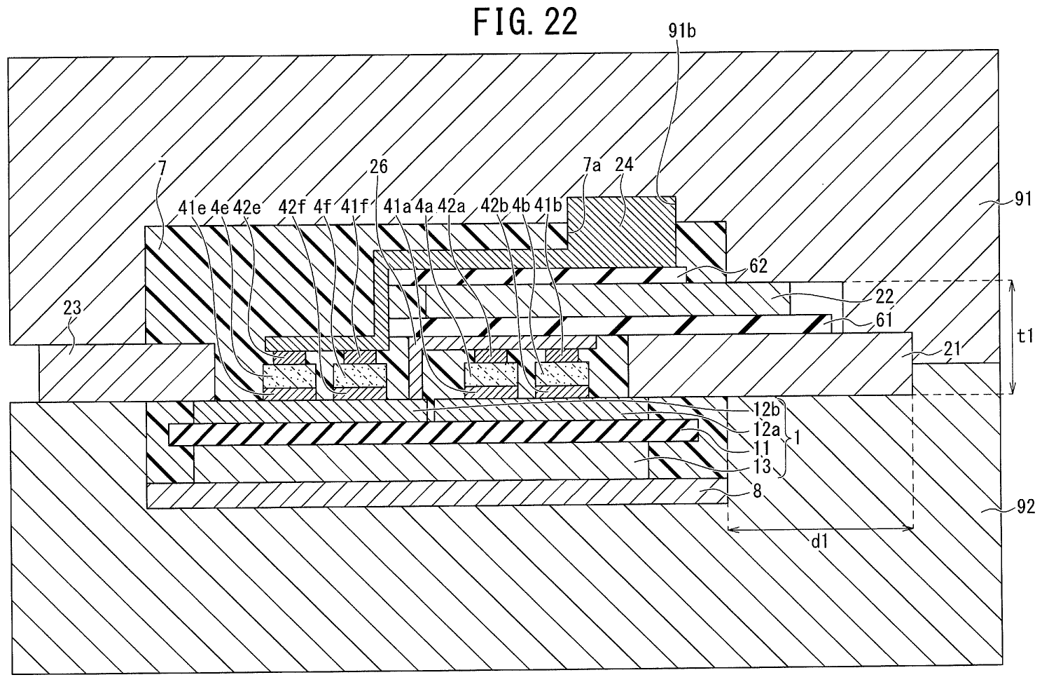

The transfer molding for the semiconductor device according to the fifth embodiment uses the metal die 91 provided with a recess 91b corresponding to the projection on the top surface side of the intermediate terminal 24, as illustrated in FIG. 22. The other configurations of the semiconductor device according to the fifth embodiment are substantially the same as those of the semiconductor device according to the first embodiment, and overlapping explanations are not repeated below.

As described above, the semiconductor device according to the fifth embodiment has the configuration in which the three terminals of the positive electrode terminal 21, the negative electrode terminal 22, and the intermediate terminal 24 are deposited close to each other (laminated) with the respective insulating members 61 and 62 interposed, and two of the positive electrode terminal 21 and the negative electrode terminal 22 on the lower side project from the side surface of the sealing resin 7, while the other intermediate terminal 24 on the uppermost side is exposed on the top surface of the sealing resin 7. This configuration can decrease the distance d1 and the thickness t1 of the part of the positive electrode terminal 21 and the negative electrode terminal 22 projecting from the sealing resin 7, so as to achieve a reduction in the entire size, as compared with a case in which three of the positive electrode terminal 21, the negative electrode terminal 22, and the intermediate terminal 24 project from the side surface of the sealing resin 7. Further, the configuration in which the top surface of the intermediate terminal 24 projects upward from the top surface of the sealing resin 7 can increase the thickness of the intermediate terminal 24, so as to suppress an increase in temperature of the insulating member 62 located immediately under a welding position when the intermediate terminal 24 and a conductive member (not illustrated) are bonded together by laser welding.

### Sixth Embodiment

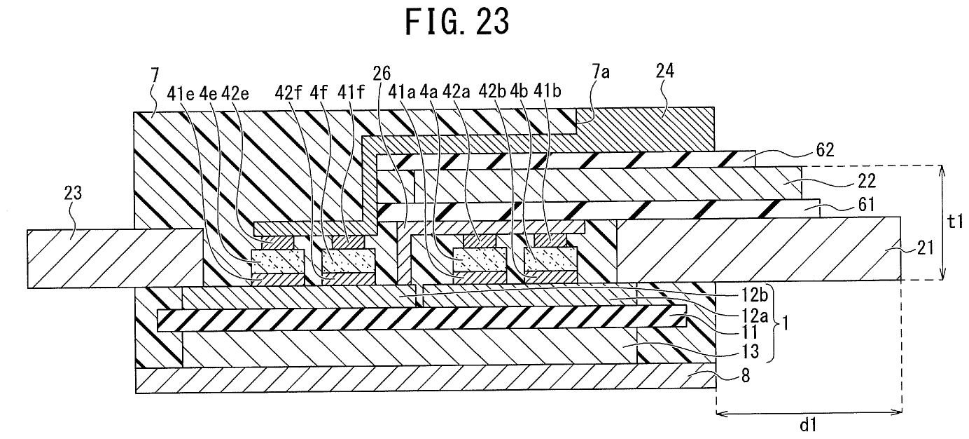

FIG. 23 is a cross-sectional view illustrating a semiconductor device according to a sixth embodiment corresponding to the position illustrated in FIG. 5. As illustrated in FIG. 23, the semiconductor device according to the sixth embodiment differs from the semiconductor device according to the first embodiment illustrated in FIG. 5 in that the opening 7a is located at the end of the top surface of the sealing resin 7. The top surface and the side surface at the end of the intermediate terminal 24 are thus exposed to the opening 7a of the sealing resin 7. The other configurations of the semiconductor device according to the sixth embodiment are substantially the same as those of the semiconductor device according to the first embodiment, and overlapping explanations are not repeated below.

As described above, the semiconductor device according to the sixth embodiment has the configuration in which the three terminals of the positive electrode terminal 21, the negative electrode terminal 22, and the intermediate terminal 24 are deposited close to each other (laminated) with the respective insulating members 61 and 62 interposed, and two of the positive electrode terminal 21 and the negative electrode terminal 22 on the lower side project from the side surface of the sealing resin 7, while the other intermediate terminal 24 on the uppermost side is exposed on the top surface of the sealing resin 7. This configuration can decrease the distance d1 and the thickness t1 of the part of the positive electrode terminal 21 and the negative electrode terminal 22 projecting from the sealing resin 7, so as to achieve a reduction in the entire size, as compared with a case in which three of the positive electrode terminal 21, the negative electrode terminal 22, and the intermediate terminal 24 project from the side surface of the sealing resin 7.

### Other Embodiments

As described above, the invention has been described according to the first to sixth embodiments, but it should not be understood that the description and drawings implementing a portion of this disclosure limit the invention. Various alternative embodiments of the present invention, examples, and operational techniques will be apparent to those skilled in the art from this disclosure.

For example, while the first, fourth, and sixth embodiments have been illustrated with the laminate wiring structure including the positive electrode terminal 21, the negative electrode terminal 22, and the intermediate terminal 24 deposited in this order from the lower side, the deposited order may be changed as appropriate. The laminate wiring structure may include the positive electrode terminal 21, the intermediate terminal 24, and the negative electrode terminal 22 deposited in this order from the lower side, for example. Alternatively, the position of any of the positive electrode terminal 21, the negative electrode terminal 22, and the intermediate terminal 24 may be replaced with the position of the output terminal 23.

While the second embodiment has been illustrated with the laminate wiring structure including the positive electrode terminal 21 and the negative electrode terminal 22 deposited sequentially from the lower side, the laminate wiring structure may include the negative electrode terminal 22 and the positive electrode terminal 21 deposited sequentially from the lower side. Alternatively, the position of either the positive electrode terminal 21 or the negative electrode terminal 22 may be replaced with the position of the output terminal 23.

While the first to sixth embodiments have been illustrated with the semiconductor device having the two-level circuit or three-level circuit configuration, the present invention may also be applied to a semiconductor device implementing a multiple-level circuit such as a four-level circuit.

The configurations disclosed in the first to sixth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
an insulated circuit substrate;
a semiconductor chip provided on a top surface side of the insulated circuit substrate;
a sealing resin provided so as to seal the semiconductor chip;
a first external terminal electrically connected to the semiconductor chip so as to be exposed on a first side surface of the sealing resin;
a second external terminal electrically connected to the semiconductor chip and having a part opposed parallel to the first external terminal on an upper side of the first external terminal so as to be exposed on a top surface of the sealing resin; and
a first insulating member interposed between the first external terminal and the second external terminal.

2. The semiconductor device of claim 1, further comprising:
a third external terminal electrically connected to the semiconductor chip and having a part opposed parallel to the first external terminal on a lower side of the first external terminal so as to be exposed on the first side surface of the sealing resin; and
a second insulating member interposed between the first external terminal and the third external terminal.

3. The semiconductor device of claim 1, further comprising a third external terminal electrically connected to the semiconductor chip and having a part laterally opposed parallel to the second external terminal so as to be exposed on the first side surface of the sealing resin.

4. The semiconductor device of claim 1, further comprising a third external terminal electrically connected to the semiconductor chip so as to be exposed on a second side surface of the sealing resin opposed to the first side surface.

5. The semiconductor device of claim 2, further comprising a fourth external terminal electrically connected to the semiconductor chip so as to be exposed on a second side surface of the sealing resin opposed to the first side surface.

6. The semiconductor device of claim 1, wherein a top surface of the second external terminal exposed on the top surface of the sealing resin has a plane common to the top surface of the sealing resin.

7. The semiconductor device of claim 1, wherein a top surface of the second external terminal exposed on the top surface of the sealing resin is recessed downward from the top surface of the sealing resin.

8. The semiconductor device of claim 1, wherein a top surface of the second external terminal exposed on the top surface of the sealing resin projects upward from the top surface of the sealing resin.

9. The semiconductor device of claim 1, wherein the second external terminal is opposed parallel to the first external terminal on an inside of the sealing resin.

10. The semiconductor device of claim 2, wherein the third external terminal is opposed parallel to the first external terminal from an inside to an outside of the sealing resin.

11. The semiconductor device of claim 1, wherein a thickness of a part of the second external terminal exposed on the top surface of the sealing resin is greater than a thickness of a part of the second external terminal not exposed on the top surface of the sealing resin.
